(19) United States
(12) Patent Application Publication
(10) Pub. No.: US 2026/0362595 A1
(43) Pub. Date: Nov. 12, 2026

(54) WIRING CIRCUIT BOARD

(71) Applicant: NITTO DENKO CORPORATION, Osaka (JP)

(72) Inventors: Takahiro IKEDA, Osaka (JP); Shusaku SHIBATA, Osaka (JP); Teppei NIINO, Osaka (JP); Hiroaki MACHITANI, Osaka (JP)

(73) Assignee: NITTO DENKO CORPORATION, Osaka (JP)

(21) Appl. No.: 19/491,673

(22) PCT Filed: Jun. 5, 2024
(86) PCT No.: PCT/JP2024/020511

§ 371 Date: Dec. 9, 2025

(30) Foreign Application Priority Data
Jun. 13, 2023 (JP) 2023-096936

(51) Int. Cl. H05K 1/11

(52) U.S. Cl. CPC H05K 1/111; H05K 2201/09227

(57) ABSTRACT

The wiring circuit board includes a frame, a mounting portion, and a joint. Each of the frame and the mounting portion includes a base insulating layer, a wiring layer, a cover insulating layer, a second wiring layer, and a second cover insulating layer. Each of the frame and mounting portion may include a support layer. The joint does not include the support layer. The joint includes the base insulating layer, the wiring layer, the cover insulating layer, the second wiring layer, and the second cover insulating layer.

### TECHNICAL FIELD

The present invention relates to a wiring circuit board.

### BACKGROUND ART

A wiring circuit board for mounting an imaging device has been known (for example, see Patent Document 1 below). The wiring circuit board described in Patent Document 1 includes a frame, a mounting portion surrounded by the frame, and a support member for connecting them. The support member is made of a rigid material. Examples of the rigid material include stainless steel. The wiring circuit board described in Patent Document 1 is provided in an imaging apparatus while the imaging device is mounted on the mounting portion. In the wiring circuit board described in Patent Document 1, the frame elastically supports the mounting portion with the support member.

When the imaging device moves (vibrates), the frame moves (vibrates). Then, the mounting portion shakes (wobbles) in accordance with the movement of the frame (vibration). However, the above-described shake (wobble) of the mounting portion is corrected with the support member. The above-described correction is referred to as shake correction (wobble-correction).

### CITATION LIST

### Patent Document

Patent Document 1: Published Japanese Translations of PCT International Publication for Patent Applications No. 2020-30306

### SUMMARY OF THE INVENTION

### Problem to be Solved by the Invention

Depending on the use and purpose of the wiring circuit board, there is a demand that the shake correction of the mounting portion be carried out with a small force. However, there is a problem that the wiring circuit board described in Patent Document 1 cannot meet the above-described demand.

In particular, a wiring circuit board including a support layer, a second cover insulating layer, a second wire, a base insulating layer, a wiring layer, and a cover insulating layer in order toward one side in the thickness direction is thicker than a second wiring circuit board including a support layer, a base insulating layer, and a wiring layer without including a second cover insulating layer and a second wiring layer. Therefore, it is remarkable that the above-described wiring circuit board cannot meet the above-described demand.

The present invention provides a wiring circuit board capable of correcting the shake of the mounting portion with a small force.

### Means for Solving the Problem

The present invention [1] includes a wiring circuit board comprising: a frame, a mounting portion surrounded by the frame and spaced from the frame, and a joint connecting the frame and the mounting portion, wherein each of the frame and the mounting portion includes: a base insulating layer; a wiring layer disposed on a one-side surface of the base insulating layer in a thickness direction; a cover insulating layer disposed on the one-side surface of the base insulating layer in the thickness direction, the cover insulating layer covering a part of the wiring layer; a second wiring layer disposed on an other-side surface of the base insulating layer in the thickness direction; and a second cover insulating layer disposed on the other-side surface of the base insulating layer in the thickness direction, the second cover insulating layer covering the second wiring layer, wherein each of the frame and the mounting portion may include a support layer disposed at an other side of the second cover insulating layer in the thickness direction, and wherein the joint does not include the support layer, and includes the base insulating layer, the wiring layer, the cover insulating layer, the second wiring layer, and the second cover insulating layer.

In this wiring circuit board, the joint does not include a support layer. Therefore, the stiffness of the joint is reduced. In detail, the joint includes a base insulating layer, a wiring layer, a cover insulating layer, a second wiring layer, and a second cover insulating layer, and thus is thick. However, as described above, the joint does not include a support layer, and thus the stiffness of the joint is reduced. As a result, it is possible to correct the shake of the mounting portion with a small force.

The present invention [2] includes the wiring circuit board described in the above-described [1], wherein the support layer is a metal support substrate.

In this wiring circuit board, the support layer is a metal support substrate, and thus each of the frame and the mounting portion has excellent stiffness. Therefore, the wiring circuit board reliably supports the mounting portion and the device with the frame while reliably mounting the device on the mounting portion.

The present invention [3] includes the wiring circuit board described in the above-described [2], wherein a thickness of the second wiring layer is different from a thickness of the wiring layer.

In this wiring circuit board, the second wiring layer can be used for a purpose different from that of the wiring layer.

The present invention [4] includes the wiring circuit board described in the above-described [3], wherein each of the frame and the mounting portion further includes a third adhesive layer adhering the support layer to the second cover insulating layer.

The present invention [5] includes the wiring circuit board described in the above-described [4], wherein the third adhesive layer is a conductive adhesive layer, wherein the second cover insulating layer in the frame and the joint has a second cover through hole, wherein the second wiring layer includes a ground wire, and wherein the ground wire is electrically grounded to the metal support substrate through the conductive adhesive layer having a part filled in the second cover through hole.

The present invention [6] includes the wiring circuit board described in the above-described [1], wherein the support layer is a rigid substrate including a rigid third base insulating layer and a third wiring layer in order toward the other side in the thickness direction. In this wiring circuit board, the support layer is a rigid substrate, and thus each of the frame and the mounting portion has excellent stiffness. Therefore, the wiring circuit board reliably supports the mounting portion and the device with the frame while reliably mounting the device on the mounting portion.

The present invention [7] includes the wiring circuit board described in the above-described [6], wherein each of the frame and the mounting portion further includes a second rigid substrate including a rigid fourth base insulating layer, a fourth wiring layer, and a fourth cover insulating layer in order toward one side in the thickness direction.

In this wiring circuit board, it is possible to further improve the stiffness of each of the frame and the mounting portion.

The present invention [8] includes the wiring circuit board described in the above-described [1] or [2], wherein the cover insulating layer includes an adhesive layer and a cover layer in order toward one side in the thickness direction, and wherein the second cover insulating layer includes a second adhesive layer and a second cover layer in order toward the other side in the thickness direction.

The present invention [9] includes the wiring circuit board described in the above-described [1] or [2], wherein the mounting portion has an approximately rectangular shape, and includes a side on an outer peripheral edge of the mounting portion, wherein the frame has an approximately rectangular frame shape, and includes a facing side facing the side and a non-facing side adjacent to the facing side and not facing the side, and wherein the joint connects the side and the non-facing side.

In this wiring circuit board, the joint connects a side and a non-facing side which does not face the side, and thus the joint can be elongated. Therefore, the stiffness of the joint is reduced.

The present invention [10] includes the wiring circuit board described in the above-described [1] or [2], wherein the joint has a curved shape.

In this wiring circuit board, the joint has a curved shape, and thus can improve the accuracy of the shake correction as compared with an embodiment in which the joint has a linear shape and/or bent shape.

The present invention [11] includes the wiring circuit board described in the above-described [1] or [2], wherein the mounting portion has a side on an outer peripheral edge of the mounting portion, wherein the joint includes a connecting portion through which the joint is connected to the side, and wherein a ratio (a length of the connecting portion/a length of the side) of the length of the connecting portion in a direction along the side with respect to the length of the side is 0.3 or less.

In this wiring circuit board, the ratio of the length of the connecting portion in the direction along the side with respect to the length of the side is 0.3 or less, and thus the spread of the connecting portion is suppressed. Therefore, the stiffness of the joint can be reliably reduced.

Further, when the frame is moved, and the joint flexes, and then the connecting portion spreads, the difference between the force applied to the central portion of the joint in the width direction and the force applied to one end portion of the joint in the width direction increases. Therefore, the shake of the mounting portion may not be accurately controlled.

However, in this wiring circuit board, when the frame is moved, and the joint flexes, the spread of the connecting portion is suppressed. Therefore, the difference between the force applied to the central portion of the joint in the width direction and the force applied to one end portion of the joint in the width direction decreases. Therefore, the shake of the mounting portion is accurately controlled.

The present invention [12] includes the wiring circuit board described in the above-described [1] or [2], wherein the mounting portion has a side on an outer peripheral edge of the mounting portion, and wherein the joint is connected to a central region including a central portion of the side, the central region having a length of ½ the length of the side.

In this wiring circuit board, the joint is connected to the central region. Therefore, the shake of the mounting portion is accurately controlled.

The present invention [13] includes the wiring circuit board described in the above-described [12], wherein the joint is connected to the central portion of the side.

In this wiring circuit board, the joint is connected to the central portion. Therefore, the shake of the mounting portion is accurately controlled.

The present invention [14] includes the wiring circuit board described in the above-described [1] or [2], wherein the mounting portion has a plurality of sides on an outer peripheral edge of the mounting portion, wherein a plurality of the joints are provided corresponding to the plurality of sides, and wherein among the plurality of the joints, a difference in length between a longest joint and a shortest joint is 3 mm or less.

In this wiring circuit board, the difference in length between the longest joint and the shortest joint is 3 mm or less. Therefore, the shake of the mounting portion is accurately controlled.

The present invention [15] includes the wiring circuit board described in the above-described [1] or [2], wherein the joint includes the wiring layer and the second wiring layer, wherein the wiring layer in the joint includes a joint wire, wherein the second wiring layer in the joint includes a second joint wire spaced from the joint wire when projected in the thickness direction, and wherein the base insulating layer, the cover insulating layer, and the second cover insulating layer in the joint have a slit disposed between the joint wire and the second joint wire.

In this wiring circuit board, the base insulating layer, the cover insulating layer, and the second cover insulating layer in the joint have a slit. Therefore, it is possible to further reduce the stiffness of the joint.

The present invention [16] the wiring circuit board described in the above-described [15], wherein the slit extends along the joint wire and the second joint wire, and wherein the joint has a sub-joint dividing the slit in a direction in which the slit extends, the sub-joint connecting the joint wire and the second joint wire.

In this wiring circuit board, the sub-joint makes it possible to suppress the excessive reduction in the stiffness of the joint due to the slit. Therefore, excessive deformation of the joint can be suppressed.

### Effects of the Invention

The wiring circuit board of the present invention can correct the shake of the mounting portion with a small force.

### BRIEF DESCRIPTION OF THE DRAWINGS

FIG. 1 is a plan view of one embodiment of the wiring circuit board of the present invention.

FIG. 2 is an enlarged view of the wiring circuit board shown in FIG. 1.

FIG. 3 is a sectional view taken along line A-A in FIG. 2.

FIG. 4A to FIG. 4E are views of portions of the process diagrams of producing the wiring circuit board shown in FIG. 3. FIG. 4A shows a step of preparing a three-layer substrate. FIG. 4B shows a step of forming a through hole. FIG. 4C shows a step of forming a via. FIG. 4D shows a step of forming a wiring layer and a second wiring layer. FIG. 4E shows a step of adhering the cover layer and the second cover layer to the base film.

FIG. 5A to FIG. 5D are views of portions of the process diagrams of producing the wiring circuit board shown in FIG. 3, following FIG. 4E. FIG. 5A shows the step of forming a protective layer. FIG. 5B shows a step of forming a joint. FIG. 5C shows a step of bonding the support layer to the second cover insulating layer. FIG. 5D shows a step of mounting an imaging device and an external substrate on the wiring circuit board.

FIG. 6A to FIG. 6E show process diagrams of producing the wiring circuit board of a first modified example. FIG. 6A shows a step of bonding a cover layer and a second cover layer to a base film in a frame and a mounting portion. FIG. 6B shows a step of bonding a solder resist to a base film in the joint. FIG. 6C shows a step of forming a protective layer. FIG. 6D shows a step of bonding a support layer to the frame and the mounting portion. FIG. 6E shows a step of forming a joint.

FIG. 7 is a cross-sectional view of the wiring circuit board of a second modified example.

FIG. 8A to FIG. 8E show process diagrams of the process diagram of producing the wiring circuit board of the second modified example. FIG. 8A shows a step of preparing a laminate. FIG. 8B shows a step of adhering a rigid substrate and a second rigid substrate to the laminate. FIG. 8C shows a step of forming a through hole. FIG. 8D shows a step of forming a via. FIG. 8E shows a step of forming a fourth base insulating layer.

FIG. 9 is a cross-sectional view of the wiring circuit board of a third modified example.

FIG. 10 is a plan view of the wiring circuit board of a fourth modified example.

FIG. 11 is a cross-sectional view taken along line A-A in FIG. 10.

### DESCRIPTION OF THE EMBODIMENT

### 1. One Embodiment of Wiring Circuit Board

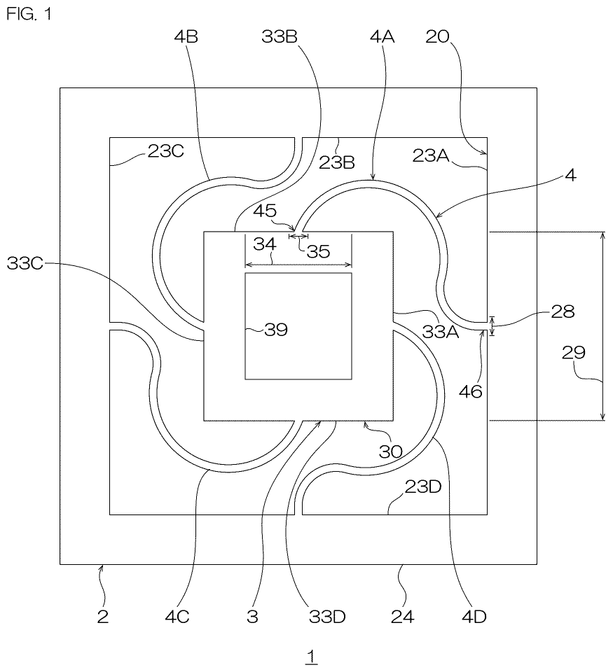

With reference to FIGS. 1 to 3, one embodiment of a wiring circuit board of the present invention is described.

### 1.1 Configuration of Wiring Circuit Board

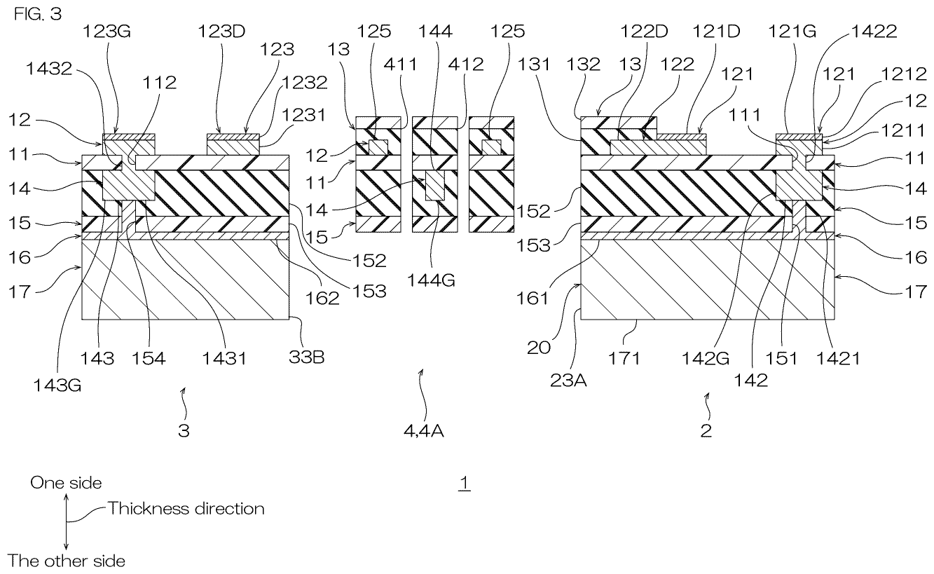

As shown in FIG. 1, a wiring circuit board 1 has a sheet shape. As shown in FIG. 3, the wiring circuit board 1 has a thickness. As shown in FIG. 1, the wiring circuit board 1 extends in a plane direction.

The plane direction is perpendicular to a thickness direction. The wiring circuit board 1 includes a frame 2, a mounting portion 3, and joints 4.

### 1.2 Frame 2

In the present embodiment, the frame 2 has an approximately rectangular frame shape. The frame 2 includes an inner peripheral edge 20. In the present embodiment, the frame 2 has four sides 23A, 23B, 23C, and 23D on the inner peripheral edge 20. The four sides 23A, 23B, 23C, and 23D are disposed counterclockwise in order in a plan view. The side 23A and the side 23C face each other. The side 23B connects one end portion of the side 23A and one end portion of the side 23C. The side 23D connects the other end portion of the side 23A and the other end portion of the side 23C. The side 23B and the side 23D face each other.

As shown in FIG. 3, the frame 2 includes a base insulating layer 11, a wiring layer 12, a cover insulating layer 13, a second wiring layer 14, a second cover insulating layer 15, a third adhesive layer 16, and a support layer 17.

### 1.2.1 Base Insulating Layer 11 in Frame 2

In the frame 2, the base insulating layer 11 extends in the plane direction. The base insulating layer 11 in the frame 2 has flexibility. The base insulating layer 11 in the frame 2 has a plurality of through holes 111. In the present embodiment, four through holes 111 are provided corresponding to the four sides 23A, 23B (see FIG. 1), 23C (see FIG. 1), and 23D (see FIG. 1), respectively.

Examples of the material of the base insulating layer 11 in the frame 2 include resin, and preferably a polyimide resin is used.

The base insulating layer 11 in the frame 2 has a thickness of, for example, 1 μm or more, preferably 5 μm or more, and, for example, 20 μm or less, preferably 15 μm or less.

### 1.2.2 Wiring Layer 12 in Frame 2

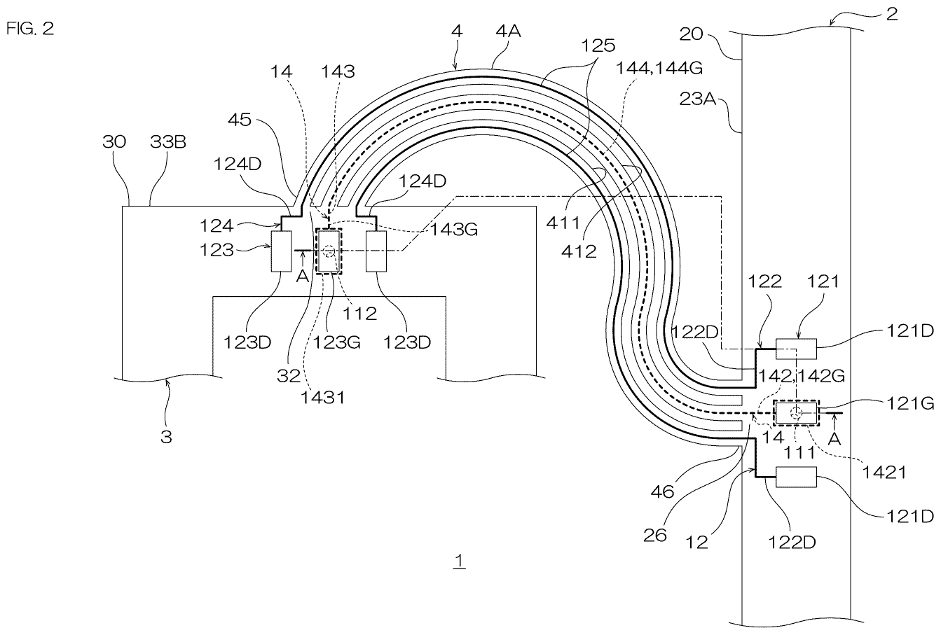

In the frame 2, the wiring layer 12 is disposed on a one-side surface of the base insulating layer 11 in the thickness direction. The wiring layer 12 is in contact with the one-side surface of the base insulating layer 11. As shown in FIG. 2, the wiring layer 12 includes a plurality of frame terminals 121 and a plurality of frame wires 122.

### 1.2.2.1 Frame Terminals 121

The plurality of frame terminals 121 are provided corresponding to each of the four sides 23A, 23B (see FIG. 1), 23C (see FIG. 1), and 23D (see FIG. 1). The plurality of frame terminals 121 corresponding to the side 23A are spaced apart from each other along the side 23A. The plurality of frame terminals 121 are aligned along the side 23A.

A plurality of frame terminals 121 includes a plurality of frame differential terminals 121D, and a frame ground terminal 121G. In the present embodiment, the frame ground terminal 121G is disposed between two frame differential terminals 121D.

As shown in FIG. 3, the frame terminal 121 includes a frame terminal body 1211 and a protective layer 1212 in order toward one side in the thickness direction. The protection layer 1212 covers a one-side surface of the frame terminal body 1211 in the thickness direction.

Although not shown, the plurality of frame terminals 121 corresponding to each of the sides 23B (see FIG. 1), 23C (see FIG. 1), and 23D (see FIG. 1) have the same configurations as those of the plurality of frame terminals 121 corresponding to the side 23A.

### 1.2.2.2 Frame Wire 122

As shown in FIG. 2, each of the plurality of frame wires 122 includes a frame differential wire 122D. The plurality of frame differential wires 122D correspond to the plurality of frame differential terminals 121D, respectively. Specifically, the plurality of frame differential wires 122D are connected to the plurality of frame differential terminals 121D, respectively. The plurality of frame differential wires 122D are spaced from each other. In the present embodiment, the plurality of frame differential wires 122D extend from the plurality of frame terminals 121, respectively, and bend, converged each other, and then reach the side 23A. The frame wires 122 corresponding to each of the sides 23B (see FIG. 1), 23C (see FIG. 1), and 23D (see FIG. 1) have the same configurations as those of the frame wires 122 corresponding to the above-described side 23A.

Examples of the material of the wiring layer 12 (frame terminal body 1211) in the frame 2 include a conductor. As the conductor, preferably, copper is used. The protective layer 1212 is a single layer or multiple layers. Examples of the material of the protective layer 1212 include gold and nickel.

The wiring layer 12 in the frame 2 has a thickness of, for example, 35 μm or less, preferably 25 μm or less, and, for example, 1 μm or more, preferably 5 μm or more.

### 1.2.3 Cover Insulating Layer 13 in Frame 2

As shown in FIG. 3, in the frame 2, the cover insulating layer 13 is disposed on the one-side surface of the base insulating layer 11 in the thickness direction. The cover insulating layer 13 covers the frame wires 122 (frame differential wire 122D, see FIG. 2) which is a part of the wiring layer 12. The cover insulating layer 13 exposes the frame terminal 121 (frame ground terminal 121G and frame differential terminal 121D) that is the remainder of the wiring layer 12. The cover insulating layer 13 has flexibility. The cover insulating layer 13 includes an adhesive layer 131 and a cover layer 132 in order toward one side in the thickness direction.

### 1.2.3.1 Adhesive Layer 131

The adhesive layer 131 in the frame 2 is in contact with the frame wires 122 and the base insulating layer 11 at the periphery of the frame wires 122. An other-side surface of the adhesive layer 131 in the thickness direction conforms to the frame wires 122. A one-side surface of the adhesive layer 131 in the thickness direction has a flat shape.

Examples of the material of the adhesive layer 131 include an adhesive composition. Examples of the adhesive composition include a polyimide adhesive composition, an epoxy adhesive composition, a silicone adhesive composition, a urethane adhesive composition, and an acrylic adhesive composition. As the adhesive composition, preferably a polyimide adhesive composition is used.

### 1.2.3.2 Cover Layer 132

The cover layer 132 is disposed on the one-side surface of the adhesive layer 131 in the thickness direction. The cover layer 132 does not have a tack. The cover layer 132 is adhered to the base insulating layer 11 and the frame wires 122 through the adhesive layer 131. Examples of the material of the cover layer 132 include polyimide resin, maleimide resin, epoxy resin, polybenzoxazole resin, and polyester resin. As the material of the cover layer 132, a polyimide resin is preferably used.

The cover insulating layer 13 in the frame 2 has a thickness of, for example, 8 μm or more, preferably 15 μm or more, and, for example, 100 μm, preferably 60 μm or less. The thickness of the cover insulating layer 13 is a length from the one-side surface of the base insulating layer 11 in the thickness direction to a one-side surface of the cover insulating layer 13 in the thickness direction.

The adhesive layer 131 in the frame 2 has a thickness of, for example, 3 μm or more, preferably 5 μm or more, and, for example, 50 μm or less, preferably 30 μm or less. The thickness of the adhesive layer 131 is a length from the one-side surface of the base insulating layer 11 in the thickness direction to the one-side surface of the adhesive layer 131 in the thickness direction.

The cover layer 132 in the frame 2 has a thickness of, for example, 5 μm or more, preferably 10 μm or more, and, for example, 50 μm or less, preferably 30 μm or less.

### 1.2.4 Second Wiring Layer 14 in Frame 2

In the frame 2, the second wiring layer 14 is disposed on an other-side surface of the base insulating layer 11 in the thickness direction. The second wiring layer 14 is in contact with the other-side surface of the base insulating layer 11 in the thickness direction. As shown with the broken line in FIG. 2, the second wiring layer 14 includes a second frame wire 142.

### 1.2.4.1 Second Frame Wire 142

The second frame wire 142 is aligned with the plurality of frame wires 122 when projected in the thickness direction. Specifically, the second frame wire 142 is disposed between two frame wires 122 when projected in the thickness direction. The second frame wire 142 includes a frame ground wire 142G.

The frame ground wire 142G is connected to the frame ground terminal 121G. A one end portion 1421 of the frame ground wire 142G has a land shape. As shown in FIG. 3, the one end portion 1421 is in contact with a frame conductive connecting portion 1422. The frame conductive connecting portion 1422 is filled in the through hole 111. The frame conductive connecting portion 1422 is in contact with an other-side surface of the frame ground terminal 121G in the thickness direction.

A thickness of the second wiring layer 14 in the mounting portion 3 is the same as or different from the thickness of the wiring layer 12 in the frame 2. The thickness of the second wiring layer 14 in the mounting portion 3 is preferably different from the thickness of the wiring layer 12 in the frame 2. In the present embodiment, the second wiring layer 14 is thicker than the wiring layer 12. The thickness of the second wiring layer 14 is, for example, 5 μm or more, preferably 10 μm or more, more preferably 20 μm or more, and, for example, 100 μm or less, preferably 50 μm or less. The ratio of the thickness of the second wiring layer 14 with respect to the thickness of the wiring layer 12 is, for example, 1.1 or more, preferably 1.2 or more, more preferably 1.5 or more, and, for example, 10 or less.

### 1.2.5 Second Cover Insulating Layer 15 in Frame 2

The second cover insulating layer 15 is disposed on the other-side surface of the base insulating layer 11 in the thickness direction. The second cover insulating layer 15 covers the second frame wires 142. In other words, the second cover insulating layer 15 covers the second wiring layer 14. The second cover insulating layer 15 has flexibility.

The second cover insulating layer 15 has a second cover through hole 151. The second cover through hole 151 is included in the one end portion 1421 of the second frame wire 142 when projected in the thickness direction. The second cover insulating layer 15 includes a second adhesive layer 152 and a second cover layer 153 in order toward the other side in the thickness direction.

### 1.2.5.1 Second Adhesive Layer 152

The second adhesive layer 152 is in contact with the second frame wire 142 and the base insulating layer 11 at the periphery of the second frame wire 142. A one-side surface of the second adhesive layer 152 in the thickness direction conforms to the second frame wire 142. An other-side surface of the second adhesive layer 152 in the thickness direction has a flat shape. As the material of the second adhesive layer 152, the materials cited as examples in the description of the adhesive layer 131 are used.

### 1.2.5.2 Second Cover Layer 153

The second cover layer 153 is disposed on the other side of the second adhesive layer 152 in the thickness direction. The second cover layer 153 does not have a tack. The second cover layer 153 is adhered to the base insulating layer 11 and the second frame wire 142 through the second adhesive layer 152. As the material of the second cover layer 153, the materials cited as examples in the description of the cover layer 132 are used.

The second cover insulating layer 15 in the frame 2 has a thickness of, for example, 8 μm or more, preferably 15 μm or more, and, for example, 100 μm, preferably 60 μm or less.

The thickness of the second cover insulating layer 15 is a length from the other-side surface of the base insulating layer 11 in the thickness direction to an other-side surface of the second cover insulating layer 15 in the thickness direction.

The second adhesive layer 152 in the frame 2 has a thickness of, for example, 3 μm or more, preferably 5 μm or more, and, for example, 50 μm or less, preferably 30 m or less. The thickness of the second adhesive layer 152 is a length from the other-side surface of the base insulating layer 11 in the thickness direction to the other-side surface of the second adhesive layer 152 in the thickness direction.

The second cover layer 153 in the frame 2 has a thickness of, for example, 5 μm or more, preferably 10 μm or more, and, for example, 50 μm or less, preferably, 30 μm or less.

### 1.2.6 Third Adhesive Layer 16 in Frame 2

The third adhesive layer 16 is disposed on the other-side surface of the second cover insulating layer 15 in the thickness direction. A part of the third adhesive layer 16 is filled in the second cover through hole 151. A part of the third adhesive layer 16 is in contact with the one end portion 1421 of the frame ground wire 142G in the second cover through hole 151. An other-side surface of the third adhesive layer 16 in the thickness direction has a flat shape.

In the present embodiment, the third adhesive layer 16 is a conductive adhesive layer 161. In other words, a part of the conductive adhesive layer 161 is filled in the second cover through hole 151. Examples of the material of the conductive adhesive layer include, for example, a composition containing metal particles and a resin and, for example, a composition containing conductive polymer particles and a resin.

The third adhesive layer 16 has a thickness of, for example, 5 μm or more, preferably 10 μm or more, and, for example, 100 μm or less, preferably 50 μm or less. The thickness of the third adhesive layer 16 is a length from the other-side surface of the second cover insulating layer 15 in the thickness direction to the other-side surface of the third adhesive layer 16 in the thickness direction.

### 1.2.7 Support Layer 17 in Frame 2

The support layer 17 in the frame 2 is disposed at the other side of the second cover insulating layer 15 in the thickness direction. In the present embodiment, the support layer 17 is in contact with the other-side surface of the third adhesive layer 16 in the thickness direction. In this manner, the support layer 17 is adhered to the other-side surface of the second cover insulating layer 15 in the thickness direction through the third adhesive layer 16. In other words, in the frame 2, the third adhesive layer 16 adheres the support layer 17 to the second cover insulating layer 15. The support layer 17 extends in the plane direction. The support layer 17 has stiffness. In the present embodiment, the support layer 17 is a metal support substrate 171. The one end portion 1421 of the frame ground wire 142G is electrically grounded to the metal support substrate 171 through the conductive adhesive layer 161.

Examples of the material of the metal support substrate 171 include a rigid material. Examples of the rigid material include stainless steel, 42 Alloy, aluminum, copper-beryllium, phosphor bronze, copper, silver, nickel, chromium, titanium, tantalum, platinum, gold, and a copper alloy. As the rigid material, from the viewpoint of ensuring the strength of the frame 2 and the mounting portion 3, preferably, stainless steel and a copper alloy are used.

The support layer 17 in the frame 2 has a thickness of, for example, 30 μm or more, preferably 100 μm or more, and, for example, 10,000 μm or less, preferably 1000 μm or less.

### 1.2.8 Dimensions of Frame 2

As shown in FIG. 1, each of the interval between the side 23A and the side 23C and the interval between the side 23B and the side 23D is, for example, 5 mm or more, preferably more than 8 mm, and, for example, 50 mm or less, preferably 30 mm or less. Each of the sides 23A, 23B, 23C and 23D has a length of, for example, 5 mm or more, preferably 8 mm or more, and, for example, 50 mm or less, preferably 30 mm or less. The frame 2 has a width of, for example, 0.1 mm or more, preferably 0.3 mm or more, and, for example, 50 mm or less, preferably 30 mm or less. The width of the frame 2 is a length between the inner peripheral edge 20 and an outer peripheral edge.

As shown in FIG. 2, each of the plurality of frame terminals 121 has a width of, for example, 10 μm or more, preferably 30 μm or more, and, for example, 3000 μm or less, preferably 1000 μm or less. The frame wire 122 each have a width of, for example, 1 μm or more, preferably 5 μm or more, and, for example, 3000 μm or less, preferably 1000 μm or less.

The one end portion 1421 of the second frame wire 142 has a width of, for example, 10 μm or more, preferably 30 μm or more, and, for example, 3000 μm or less, preferably 1000 μm or less. The second frame wire 142 other than the one end portion 1421 has a width of, for example, 1 μm or more, preferably 5 μm or more, and, for example, 3000 μm or less, preferably 1000 μm or less.

### 1.3 Mounting Portion 3

As shown in FIG. 1, the mounting portion 3 is surrounded by the frame 2. The mounting portion 3 is spaced apart from the frame 2. In the present embodiment, the mounting portion 3 has an approximately rectangular shape. Preferably, the mounting portion 3 has an approximately rectangular outer shape, specifically, has an approximately rectangular frame shape. The mounting portion 3 includes an outer peripheral edge 30 and an inner peripheral edge 39. In the present embodiment, the mounting portion 3 includes four sides 33A, 33B, 33C, and 33D on the outer peripheral edge 30.

The four sides 33A, 33B, 33C, and 33D are disposed counterclockwise in order in the plan view. The sides 33A, 33B, 33C, and 33D of the mounting portion 3 face the sides 23A, 23B, 23C, and 23D of the frame 2, respectively.

In other words, the side 33B of the mounting portion 3 faces (is opposite to) the side 23B of the frame 2. In other words, the side 23B is a facing side facing the side 33B. The side 33B extends in the same direction as the side 23B.

The side 33B of the mounting portion 3 does not face (is not opposite to) the side 23A of the frame 2. In other words, the side 23A is a non-facing side that does not face the side 33B. The side 33B is adjacent to the side 33A. The side 33B extends in a direction that intersects with the side 23A. Preferably, the side 33B extends in a direction perpendicular to the side 23A.

The side 33C is along the same direction as the side 33A. The side 33B connects one end portion of the side 33A and one end portion of the side 33C. The side 33D connects the other end portion of the side 33A and the other end portion of the side 33C. The side 33D is along the same direction as the side 33B.

As shown in FIG. 3, the mounting portion 3 includes the base insulating layer 11, the wiring layer 12, the cover insulating layer 13, the second wiring layer 14, the second cover insulating layer 15, the third adhesive layer 16, and the support layer 17.

### 1.3.1 Base Insulating Layer 11 in Mounting Portion 3

In the mounting portion 3, the base insulating layer 11 extends in the plane direction. The base insulating layer 11 in the mounting portion 3 has a plurality of through holes 112. In the present embodiment, four through holes 112 are provided corresponding to the four side 33A (see FIG. 1), 33B, 33C (see FIG. 1), and 33D (see FIG. 1), respectively. The base insulating layer 11 in the mounting portion 3 has flexibility. The material and thickness of the base insulating layer 11 in the mounting portion 3 are the same as the material and thickness of the base insulating layer 11 in the frame 2, respectively.

### 1.3.2 Wiring Layer 12 in Mounting Portion 3

In the mounting portion 3, the wiring layer 12 is disposed on the one-side surface of the base insulating layer 11 in the thickness direction. The wiring layer 12 is in contact with the one-side surface of the base insulating layer 11. As shown in FIG. 2, the wiring layer 12 in the mounting portion 3 includes a plurality of terminals 123 and a plurality of wires 124.

### 1.3.2.1 Terminals 123

The plurality of terminals 123 are provided corresponding to each of the four sides 33A (see FIG. 1), 33B, 33C (see FIG. 1), and 33D (see FIG. 1). Specifically, the plurality of terminals 123 corresponding to the side 33B are spaced from each other in a direction along the side 33B. The plurality of terminals 123 are aligned in a direction along the side 33B.

The plurality of terminals 123 includes a plurality of differential terminals 123D and a ground terminal 123G. In the present embodiment, the ground terminal 123G is disposed between two differential terminals 123D.

Although not shown, the plurality of terminals 123 corresponding to each of the side 33A (see FIG. 1), 33C (see FIG. 1), and 33D (see FIG. 1) have the same configurations as those of the terminals 123 corresponding to the side 33B.

As shown in FIG. 3, the terminal 123 includes a terminal body 1231 and a protective layer 1232 in order toward one side in the thickness direction. The protection layer 1232 covers a one-side surface of the terminal body 1231 in the thickness direction.

### 1.3.2.2 Wire 124

As shown in FIG. 2, each of the plurality of wires 124 includes a differential wire 124D. The plurality of differential wires 124D correspond to the plurality of differential terminals 123D, respectively. Specifically, the plurality of differential wires 124D are connected to the plurality of differential terminals 123D, respectively. The plurality of differential wires 124D are spaced from each other. In the present embodiment, the plurality of differential wires 124D extend from the plurality of differential terminals 123D, respectively, and converged each other, and then reach the side 33B.

The wires 124 corresponding to each of the side 33A (see FIG. 1), 33C (see FIG. 1), and 33D (see FIG. 1) have the same configurations as those of the wires 124 corresponding to the above-described side 33B.

The material and thickness of the wire 124 in the mounting portion 3 are the same as the material and thickness of the wire 124 in the frame 2, respectively.

### 1.3.3 Cover Insulating Layer 13 in Mounting Portion 3

Although not shown, in the mounting portion 3, the cover insulating layer 13 is disposed on the one-side surface of the base insulating layer 11 in the thickness direction. The cover insulating layer 13 covers the wire 124 (differential wire 124D, see FIG. 2) which is a part of the wiring layer 12. The cover insulating layer 13 exposes the terminal 123 (differential terminal 123D, ground terminal 123G, see FIG. 2) that is the remainder of the wiring layer 12. The cover insulating layer 13 has flexibility. The cover insulating layer 13 includes an adhesive layer 131 and a cover layer 132 in order toward one side in the thickness direction.

### 1.3.3.1 Adhesive Layer 131

The adhesive layer 131 (not shown) in the mounting portion 3 is in contact with the wire 124 and the base insulating layer 11 at the periphery of the wire 124. The other-side surface of the adhesive layer 131 in the thickness direction conforms to the wire 124. The one-side surface of the adhesive layer 131 in the thickness direction has a flat shape. The material and thickness of the adhesive layer 131 in the mounting portion 3 are the same as the material and thickness of the adhesive layer 131 in the frame 2, respectively.

The cover layer 132 (not shown) in the mounting portion 3 is disposed on the one-side surface of the adhesive layer 131 in the thick direction. The cover layer 132 is adhered to the base insulating layer 11 and the wire 124 through the adhesive layer 131. The material and thickness of the cover layer 132 in the mounting portion 3 are the same as the material and thickness of the cover layer 132 in the frame 2, respectively.

The thickness of the cover insulating layer 13 in the mounting portion 3 is the same as the thickness of the cover layer 132 in the frame 2.

### 1.3.4 Second Wiring Layer 14 in Mounting Portion 3

In the mounting portion 3, the second wiring layer 14 is disposed on the other-side surface of the base insulating layer 11 in the thickness direction. The second wiring layer 14 is in contact with the other-side surface of the base insulating layer 11 in the thickness direction. As shown with the broken line in FIG. 2, the second wiring layer 14 includes a second wire 143.

### 1.3.4.1 Second Wire 143

The second wire 143 is aligned with the plurality of wires 124 when projected in the thickness direction. Specifically, the second wire 143 is disposed between two wires 124 when projected in the thickness direction.

The second wire 143 includes a ground wire 143G.

The ground wire 143G is connected to the ground terminal 123G. One end portion 1431 of the second wire 143 has a land shape. As shown in FIG. 3, the one end portion 1431 is in contact with the conductive connecting portion 1432. The conductive connecting portion 1432 is filled in the through hole 112. The conductive connecting portion 1432 is in contact with the ground terminal 123G.

The thickness of the second wiring layer 14 in the mounting portion 3 is the same as the thickness of the second wiring layer 14 in the frame 2.

### 1.3.5 Second Cover Insulating Layer 15 in Mounting Portion 3

The second cover insulating layer 15 in the mounting portion 3 is disposed on the other-side surface of the base insulating layer 11 in the thickness direction. The second cover insulating layer 15 covers the second wire 143. In other words, the second cover insulating layer 15 covers the second wiring layer 14. The second cover insulating layer 15 has flexibility. The second cover insulating layer 15 has a second cover through hole 154. The second cover through hole 154 is included in the one end portion 1431 of the second wire 143 when projected in the thickness direction. The second cover insulating layer 15 in the mounting portion 3 includes a second adhesive layer 152 and a second cover layer 153 in order toward the other side in the thickness direction.

### 1.3.5.1 Second Adhesive Layer 152

The second adhesive layer 152 is in contact with the second wire 143 and the base insulating layer 11 at the periphery of the second wire 143. A one-side surface of the second adhesive layer 152 in the thickness direction conforms to the ground wire 143G. An other-side surface of the second adhesive layer 152 in the thickness direction has a flat shape. The material and thickness of the second adhesive layer 152 in the mounting portion 3 are the same as the material and thickness of the second adhesive layer 152 in the frame 2, respectively.

### 1.3.5.2 Second Cover Layer 153

The second cover layer 153 is disposed on the other-side surface of the second adhesive layer 152 in the thickness direction. The second cover layer 153 is adhered to the base insulating layer 11 and the second wire 143 through the second adhesive layer 152. In other words, the second adhesive layer 152 adheres the second cover layer 153 to the base insulating layer 11 and the second wire 143. The material and thickness of the second cover layer 153 in the mounting portion 3 are the same as the material and thickness of the second cover layer 153 in the frame 2, respectively.

The thickness of the second cover insulating layer 15 in the mounting portion 3 is the same as the thickness of the second cover insulating layer 15 in the frame 2.

### 1.3.6 Third Adhesive Layer 16 in Mounting Portion 3

The third adhesive layer 16 is disposed on the other-side surface of the second cover insulating layer 15 in the thickness direction. A part of the third adhesive layer 16 is filled in the second cover through hole 154. A part of the third adhesive layer 16 is in contact with the one end portion 1431 of the second wire 143 in the second cover through holes 154.

The one-side surface of the third adhesive layer 16 in the thickness direction conforms to the shape of the second cover insulating layer 15.

The other-side surface of the third adhesive layer 16 in the thickness direction has a flat shape.

In the present embodiment, the third adhesive layer 16 is a conductive adhesive layer 162. In other words, a part of the conductive adhesive layer 162 is filled in the second cover through hole 154. The material and thickness of the third adhesive layer 16 in the mounting portion 3 are the same as the material and thickness of the third adhesive layer 16 in the frame 2, respectively.

### 1.3.7 Support Layer 17 in Mounting Portion 3

The support layer 17 in the mounting portion 3 is disposed at the other side of the second cover insulating layer 15 in the thickness direction. In the present embodiment, the support layer 17 is in contact with the other-side surface of the third adhesive layer 16 in the thickness direction. In this manner, the support layer 17 is adhered to the other-side surface of the second cover insulating layer 15 in the thickness direction through the third adhesive layer 16. In other words, in the mounting portion 3, the third adhesive layer 16 adheres the support layer 17 to the second cover insulating layer 15. The one end portion 1431 of the ground wire 143G is electrically grounded to the metal support substrate 171 through the conductive adhesive layer 162. The support layer 17 extends in the plane direction. The support layer 17 has stiffness. In the present embodiment, the support layer 17 is a metal support substrate 172. The material and thickness of the support layer 17 in the mounting portion 3 are the same as the material and thickness of the support layer 17 in the frame 2, respectively.

### 1.3.8 Dimensions of Mounting Portion 3

As shown in FIG. 1, each of the interval between the side 33A and the side 33C and the interval between the side 33B and the side 33D is, for example, 3 mm or more, preferably more than 5 mm, and, for example, 50 mm or less, preferably 30 mm or less. Each of the sides 33A, 33B, 33C, and 33D has a length of, for example, 3 mm or more, preferably 5 mm or more, and, for example, 50 mm or less, preferably 30 mm or less.

The mounting portion 3 has a width of, for example, 0.3 mm or more, preferably 0.5 mm or more, and, for example, 30 mm or less, preferably is 20 mm or less. The width of the mounting portion 3 is a length between the outer peripheral edge 30 and the inner peripheral edge 39.

As shown in FIG. 2, the width of each of the plurality of terminals 123 is the same as the above-described width of each of the plurality of frame terminals 121. The width of the wire 124 is the same as the above-described width of the frame wire 122. The width of the second wire 143 is the same as the above-described width of the second frame wires 142.

### 1.4 Joint 4

The joint 4 is disposed between the frame 2 and the mounting portion 3. The joint 4 connects the frame 2 and the mounting portion 3. A plurality of joints 4 are provided corresponding to the plurality of sides 33 in the mounting portion 3. As shown in FIG. 1, in the present embodiment, the plurality of joints 4A, 4B, 4C, and 4D correspond to the plurality of sides 33B, 33C, 33D, and 33A in the mounting portion 3, respectively. Specifically, the joint 4A connects the side 23A of the frame 2 and the side 33B of the mounting portion 3. The joint 4B connects the side 23B of the frame 2 and the side 33C of the mounting portion 3. The joint 4C connects the side 23C of the frame 2 and the side 33D of the mounting portion 3. The joint 4D connects the side 23D of the frame 2 and the side 33A of the mounting portion 3.

Hereinafter, the details of the joint 4A are described. The joints 4B, 4C, and 4D have the same configuration as that of the joint 4A, and the detailed descriptions of them are omitted.

### 1.4.1 Shape of Joint 4A

As shown in FIG. 2, in the present embodiment, the joint 4A has a curved-shape in a plan view. Preferably, the joint 4A does not have a straight shape and/or a bent shape and only has a curved shape. Specifically, the joint 4A has an S-shape or a hook shape. When the joint 4A has a curved shape, the stress can be evenly relaxed without being concentrated locally. Thus, the accuracy of the shake correction of the mounting portion 3 can be improved.

### 1.4.2 Connection of Joint 4 to Mounting Portion 3

The joint 4A is connected to a converging portion 32 in the mounting portion 3. In the converging portion 32, the plurality of wires 124 are converged.

The joint 4A includes a connecting portion 45. As shown in FIG. 1, for example, the connecting portion 45 is connected to a central region 34 of the side 33B in the mounting portion 3.

The central region 34 is a region including a central portion 35 in the side 33B. The central portion 35 is a central point and the vicinity thereof in the side 33B. The central region 34 has a length of ½ the length of the side 33B. The central region 34 preferably has a length of ⅓ the length of the side 33B, and more preferably has a length of ¼ the length of the side 33B.

Preferably, the joint 4A is connected to the central portion 35 of the side 33B. The ratio (the length of the connecting portion 45/the length of the side 33B) of the length of the connecting portion 45 in the direction along the side 33B with respect to the length of the side 33B is, for example, 0.3 or less, preferably 0.25 or less, more preferably 0.2 or less, and, for example, 0.01 or more.

When the ratio of the length of the connecting portion 45 in the direction along the side 33B with respect to the length of the side 33B is the above-described upper limit or less, the spread of the connecting portion 45 in the direction in which the side 33B extends is suppressed. Therefore, the stiffness of the jointed 4A can be reliably reduced.

### 1.4.3 Connection of Joint 4 to Frame 2

As shown in FIG. 2, the joint 4A is connected to the frame converging portion 26 in frame 2. The joint 4A includes a second connecting portion 46. As shown in FIG. 1, for example, the second connecting portion 46 is connected to a second central region 29 of the side 23A in the frame 2.

The second central region 29 is a region including a second central portion 28 in the side 23A. The second central portion 28 is a central point and the vicinity thereof in the side 23A. The second central region 29 has a length of ½ the length of the side 23A. Preferably, the second central region 29 has a length of ⅓ the length of the side 23A. More preferably, the second central region 29 has a length of ¼ the length of the side 23A.

Preferably, the joint 4A is connected to the second central portion 28 of the side 23A. The ratio (the length of the second connecting portion 46/the length of the side 23A) of the length of the second connecting portion 46 in the direction along the side 23A with respect to the length of the side 23A is, for example, 0.3 or less, preferably 0.25 or less, more preferably 0.2 or less, and, for example, 0.01 or more.

When the ratio of the length of the second connecting portion 46 in the direction along the side 23A with respect to the length of the side 23A is the above-described upper limit or less, the spread of the second connecting portion 46 in the direction in which the side 23A extends is suppressed. Therefore, the stiffness of the joint 4A can be reliably reduced.

### 1.4.4. Layer Structure of Joint 4A

As shown in FIG. 3, the joint 4A includes the base insulating layer 11, the wiring layer 12, the cover insulating layer 13, the second wiring layer 14, and the second cover insulating layer 15.

The joint 4A does not include at least a support layer 17. In the present embodiment, the joint 4A does not include the third adhesive layer 16 and the support layer 17.

### 1.4.5 Base Insulating Layer 11 in Joint 4A

As shown in FIG. 2, the base insulating layer 11 in the joint 4A includes slits 411 and 412. Each of the slits 411 and 412 is along the wiring layer 12 and the second wiring layer 14. The material and thickness of the base insulating layer 11 in the joint 4A are the same as the material and thickness of the base insulating layer 11 in the frame 2, respectively.

### 1.4.6 Wiring Layer 12 in Joint 4A

The wiring layer 12 in the joint 4A include a joint wire 125. In the present embodiment, the wiring layer 12 in the joint 4A includes only the joint wire 125. As shown in FIG. 3, the joint wire 125 is disposed on the one-side surface of the base insulating layer 11 in the thickness direction. The joint wire 125 is in contact with the one-side surface of the base insulating layer 11 in the thickness direction. Both end portions of the joint wire 125 are connected to the frame differential wire 122D and the differential wire 124D, respectively. In the present embodiment, the two joint wires 125 can function as differential wires. For example, the two joint wires 125 operate as a differential pair. The material and thickness of the wiring layer 12 in the joint 4A are the same as the material and thickness of the wiring layer 12 in the frame 2, respectively.

### 1.4.7 Cover Insulating Layer 13 in Joint 4A

The cover insulating layer 13 in the joint 4A extends in the direction in which the wiring layer 12 and the second wiring layer 14 extend. The cover insulating layer 13 is disposed on the one-side surface of the base insulating layer 11 in the thickness direction. The cover insulating layer 13 in the joint 4A covers the wiring layer 12. The covering insulating layer 13 in the joint 4A includes the slits 411 and 412 together with the base insulating layer 11. The configuration, material, and thickness of the cover insulating layer 13 in the joint 4A is the same as the configuration, material, and thickness of the cover insulating layer 13 in the frame 2, respectively. The cover insulating layer 13 in the joint 4A includes an adhesive layer 131 and a cover layer 132 in order toward one side in the thickness direction.

### 1.4.8 Second Wiring Layer 14 in Joint 4A

The second wiring layer 14 in the joint 4A includes a second joint wire 144. In the present embodiment, the second wiring layer 14 in the joint 4A includes only the second joint wire 144. The second joint wire 144 is disposed on the other-side surface of the base insulating layer 11 in the thickness direction. The second joint wire 144 is in contact with the other-side surface of the base insulating layer 11 in the thickness direction. The second joint wire 144 is spaced apart from the joint wire 125 when projected in the thickness direction. The second joint wire 144 is disposed between the joint wires 125. Both end portions of the joint wire 125 are connected to the frame ground wire 142G and the ground wire 143G, respectively. Therefore, the second joint wire 144 functions as the joint ground wiring 144G. The material and thickness of the second wiring layer 14 in the joint 4A are the same as the material and thickness of the second wiring layer 14 in the frame 2, respectively.

### 1.4.9 Second Cover Insulating Layer 15 in Joint 4A

The second cover insulating layer 15 in the joint 4A extends in the direction in which the wiring layer 12 and the second wiring layer 14 extend. The second cover insulating layer 15 is disposed on the other-side surface of the base insulating layer 11 in the thickness direction. The second cover insulating layer 15 covers the second wire 143. The cover insulating layer 13 in the joint 4A includes the slits 411 and 412 together with the base insulating layer 11 and the cover insulating layer 13. The material and thickness of the second cover insulating layer 15 in the joint 4A are the same as the material and thickness of the second cover insulating layer 15 in the frame 2, respectively.

Each of the joint wires 125 and the second joint wire 144 has a width of, for example, 10 μm or more, preferably 30 μm or more, and, for example, 3000 μm or less, preferably 1000 μm or less.

### 1.4.10 Slits 411 and 412

As shown in FIG. 2, the plurality of slits 411 and 412 are spaced from each other in a direction (an intersecting direction, preferably a perpendicular direction) intersecting the direction in which the joint 4 extends.

Each of the plurality of slits 411 and 412 is disposed entirely in the direction in which the joint 4 extends in the joint 4. The plurality of slits 411 and 412 are aligned in order in the intersecting direction. The plurality of slits 411 and 412 partition the wiring layers 12 and the second wiring layer 14 when projected in the thickness direction. Specifically, the joint wire 125, the slit 411, the second joint wire 144, the slit 412, and the joint wire 125 are aligned in order in the intersecting direction. In other words, each of the slits 411 and 412 is disposed between the joint wire 125 and the second joint wire 144.

Each of the slits 411 and 412 has a width of, for example, 5 μm or more, preferably 10 μm or more, and, for example, 500 μm or less, preferably 300 μm or less.

The plurality of joints 4A, 4B, 4C, and 4D may have the same length or different lengths. When the plurality of joints 4A, 4B, 4C, and 4D have different lengths from each other, the difference in length between the longest joint 4 and the shortest joint 4 is, for example, 3 mm or less, preferably 2 mm or less, and more preferably 1.5 mm or less. When the difference in length between the longest joint 4 and the shortest joint 4 is the above-described upper limit or less, the accuracy of the shake correction of the mounting portion 3 is improved.

### 1.5 Method of Producing Wiring Circuit Board 1

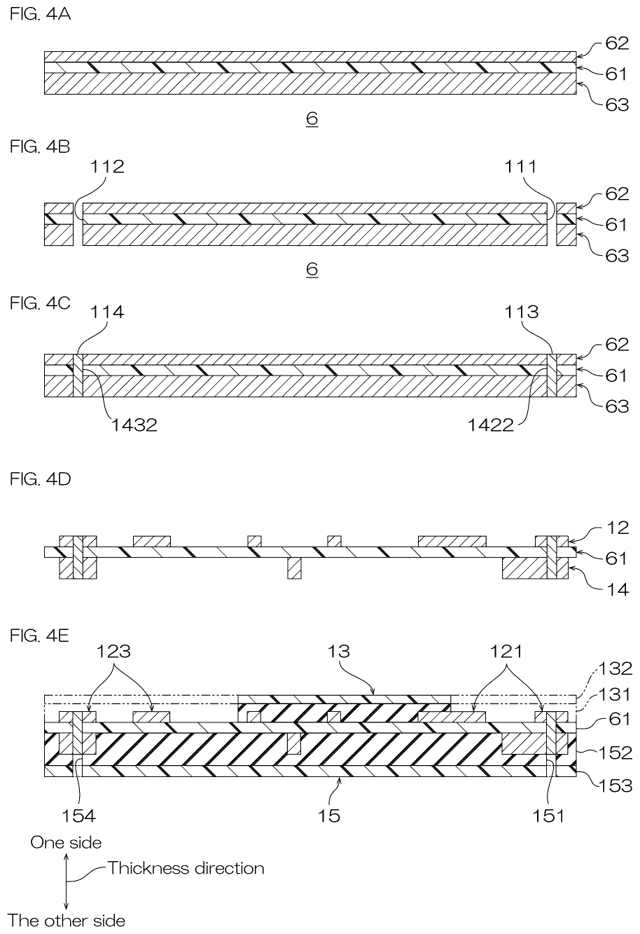

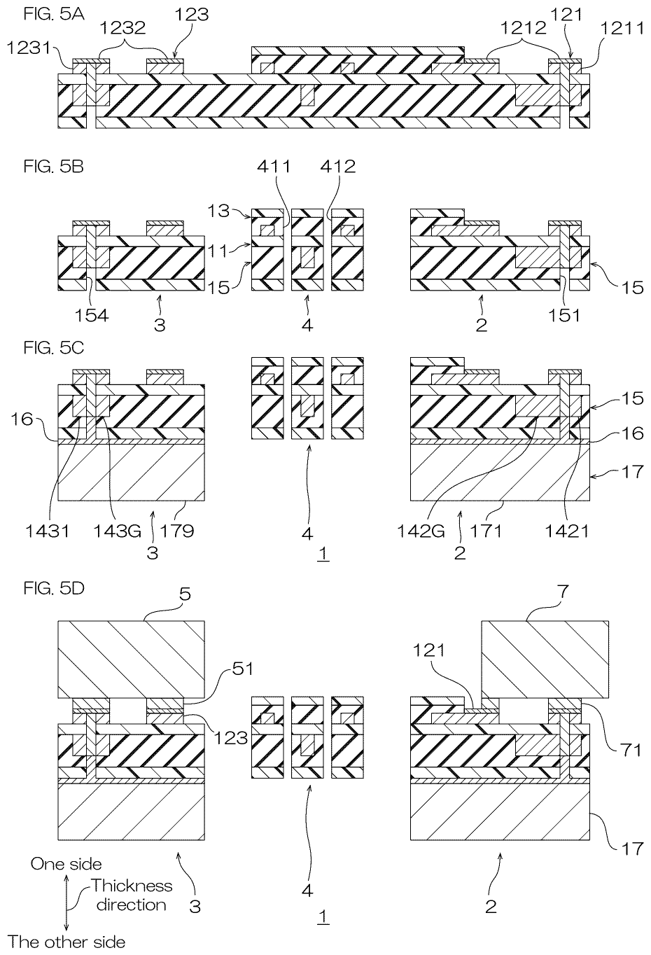

Next, with reference to FIGS. 4A to 5D, the method of producing the wiring circuit board 1 and the mounting of the imaging device 5 are described.

As shown in FIG. 4A, in this method, first, a three-layer substrate 6 is prepared. The three-layer substrate 6 extends in the plane direction. The three-layer substrate 6 includes a base film 61, a conductor foil 62, and a second conductor foil 63.

The base film 61 extends in the plane direction.

The conductor foil 62 is disposed on a one-side surface of the base film 61 in the thickness direction. The conductor foil 62 is in contact with the entire one-side surface of the base film 61.

The second conductor foil 63 is disposed on an other-side surface of the base film 61 in the thickness direction. The second conductor foil 63 is in contact with the entire other-side surface of the base film 61.

As shown in FIG. 4B, in this method, next, each of through holes 111 and 112 is formed in the three-layer substrate 6. In the formation of the through holes 111 and 112, for example, laser processing is used. Each of the through holes 111 and 112 penetrates the three-layer substrate 6 in the thickness direction.

As shown in FIG. 4C, in this method, next, vias 113 and 114 are formed in the through holes 111 and 112, respectively. In the formation of the vias 113 and 114, for example, through hole plating is used.

The via 113 includes a frame conductive connecting portion 1422 at its intermediate portion in the thickness direction. The frame conductive connecting portion 1422 is filled in the through hole 111 of the base film 61.

The via 114 includes a conductive connecting portion 1432 at its intermediate portion in the thickness direction. The conductive connecting portion 1432 is filled in the through hole 112 of the base film 61.

As shown in FIG. 4D, in this method, next, a wiring layer 12 is formed from the conductor foil 62, and a second wiring layer 14 is formed from the second conductor foil 63.

In the formation of the wiring layer 12 and the second wiring layer 14, etching of each of the conductor foil 62 and the second conductor foil 63 is used. An etching resist not shown is used in the etching. The etching resist is prepared by exposing a dry film resist not shown to light and developing it.

As shown in FIG. 4E, in this method, next, a cover insulating layer 13 and a second cover insulating layer 15 are formed on the one-side surface and the other-side surface of the base film 61 in the thickness direction, respectively.

For example, a cover layer 132 is bonded to the one-side surface of the base film 61 and a one-side surface of the conductor foil 62 in the thickness direction through an adhesive layer 131. Thereafter, the outer shapes of the cover layer 132 and the adhesive layer 131 are trimmed to expose frame terminals 121 and terminals 123. In the trim of the outer shapes of the cover layer 132 and the adhesive layer 131, for example, laser processing is used.

For example, a second cover layer 153 is bonded to the other-side surface of the base film 61 and an other-side surface of the second conductor foil 63 in the thickness direction through a second adhesive layer 152. Thereafter, second cover through holes 151 and 154 are formed in the second cover layer 153 and the second adhesive layer 152. In the formation of the second cover through holes 151 and 154, for example, laser processing is used.

As shown in FIG. 5A, in this method, next, protective layers 1212 and 1232 are formed on the frame terminal body 1211 and the terminal body 1231, respectively. In the formation of the protective layers 1212 and 1232, for example, plating is used. In this manner, each of the frame terminal 121 and the terminal 123 is formed.

As shown in FIG. 5B, in this method, next, slits 411 and 412 are formed in the base insulating layer 11, the cover insulating layer 13, and the second cover insulating layer 15. In the formation of the slits 411 and 412, for example, laser processing is used.

As shown in FIG. 5C, a support layer 17 is bonded to the other-side surface of the second cover insulating layer 15 in the thickness through the third adhesive layer 16. At this time, a part of the third adhesive layer 16 is filled in the second cover through holes 151 and 154. In this manner, one end portion 1421 of a frame ground wire 142G is electrically grounded through the third adhesive layer 16 to the metal support substrate 171, and one end portion 1431 of a ground wire 143G is electrically grounded through the third adhesive layer 16 to the metal support substrate 172.

In this manner, a wiring circuit board 1 is produced.

Thereafter, as shown in FIG. 5D, an imaging device 5 is mounted on the mounting portion 3. An electrode 51 of the imaging device 5 and the plurality of terminals 123 in the mounting portion 3 are electrically connected. The imaging device 5 can be mounted on the mounting portion 3 via a mounting substrate not shown.

Together with the above, an external substrate 7 is mounted on the frame 2. An electrode 71 of the external substrate 7 and the plurality of frame terminals 121 in the frame 2 are electrically connected. An outer side 24 (see FIG. 1) of the frame 2 may be supported by an outer member (not shown).

### 2. Operations and Effects of One Embodiment

In this wiring circuit board 1, the joints 4 do not include the support layer 17. Therefore, the stiffness of the joints 4 is reduced. In detail, the joints 4 include the base insulating layer 11, the wiring layer 12, the cover insulating layer 13, the second wiring layer 14, and the second cover insulating layer 15, and is thick. However, as described above, the joints 4 do not include the support layer 17, and thus the stiffness of the joint 4 is reduced. As a result, the shake correction of the mounting portion 3 can be carried out with a small force.

Furthermore, the wiring circuit board 1 includes the wiring layer 12 and the second wiring layer 14 on both sides of the cover insulating layer 13 in the thickness direction, and thus the degree of freedom of design (arrangement) of the circuit (wiring pattern) is increased.

In the wiring circuit board 1, the support layer 17 is the metal support substrate 171, and thus each of the frame 2 and the mounting portion 3 has excellent stiffness. Therefore, the wiring circuit board 1 can reliably support the imaging device 5 and the mounting portion 3 with the frame 2 while reliably mounting the imaging device 5 on the mounting portion 3.

In the wiring circuit board 1, the second wiring layer 14 and the wiring layer 12 are different in thickness, and thus the second wiring layer 14 can be used for a purpose different from the wiring layer 12. Specifically, the second wiring layer 14 can be made thicker than the wiring layer 12 and function as a ground layer capable of flowing a large current. In the wiring circuit board 1, the joint 4A connects the side 33B to the non-facing side 23A that does not face the side 33B, and thus it is possible to elongate the joint 4A. Therefore, the stiffness of the jointed 4A is reduced.

In this wiring circuit board, the joint 4A has a curved shape, and thus the accuracy of the shake correction is improved as compared with an embodiment in which the joint 4A has a linear shape and/or bent shape.

In the wiring circuit board 1, the ratio of the length of the connecting portion 45 in the direction along the side 33B with respect to the length of the side 33B is 0.3 or less, and thus the spread of the connecting portion 45 is suppressed. Therefore, the stiffness of the joint 4A can be reliably reduced.

In the wiring circuit board 1, the joint 4A is connected to the central region 34, and thus the shake of the mounting portion 3 can be accurately controlled.

In the wiring circuit board 1, the joints 4 are connected to the central portions 35, and thus the shake of the mounting portion 3 can be accurately controlled.

In this wiring circuit board, the base insulating layer 11, the cover insulating layer 13, and the second cover insulating layer 15 in the joint 4A have the slits 411 and 412, and thus it is possible to further reduce the stiffness of the joint 4A.

### 3. Modified Examples

In each of the modified examples below, the same members and steps as in the above-described one embodiment are given the same numerical references, and the detailed descriptions thereof are omitted. Further, each modified example can achieve the same operations and effects as those of one embodiment unless otherwise specified. Furthermore, one embodiment and each modified example can be appropriately combined.

### 3.1 First Modified Example

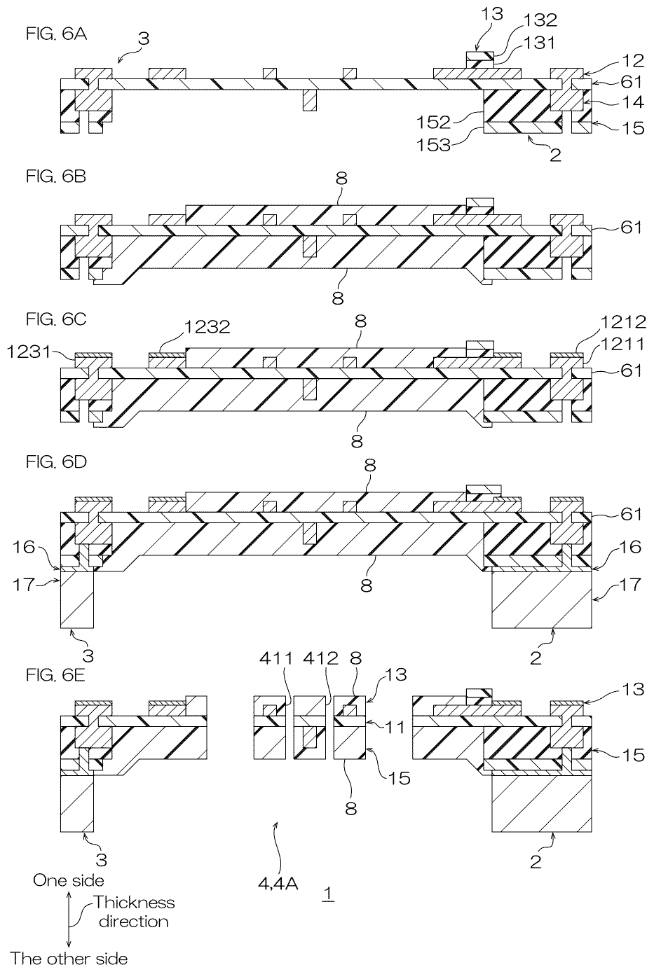

As shown in FIG. 6E, the cover insulating layer 13 and the second cover insulating layer 15 may include a solder resist 8. At least each of the cover insulating layer 13 and the second cover insulating layer 15 in the joint 4A only includes the solder resist 8 and does not include the adhesive layer 131 and the second adhesive layer 152.

With reference to FIGS. 6A to 6E, the method of producing the wiring circuit board 1 of a first modified example is described.

As shown in FIG. 6A, the cover layer 132 and the adhesive layer 131 are disposed on the one-side surface of the base film 61 in the frame 2 and the mounting portion 3. The second cover layer 153 and the second adhesive layer 152 are disposed on the other-side surface of the base film 61 in the frame 2 and the mounting portion 3.

As shown in FIG. 6B, the solder resist 8 is disposed on the one-side surface and the other-side surface of the base film 61 in the joints 4. The solder resist 8 is formed into a pattern by a photo process.

As shown in FIG. 6C, the protective layers 1212 and 1232 are formed on the frame terminal body 1211 and the terminal body 1231, respectively.

As shown in FIG. 6D, the support layer 17 and the third adhesive layer 16 are disposed on the frame 2 and the mounting portion 3.

As shown in the FIG. 6E, the slits 411 and 412 are formed in the solder resist 8.

### 3.1.1 Operations and Effects of First Modified Example

In the first modified example, the solder resist 8 in the joint 4A does not include the adhesive layer 131 and the second adhesive layer 152, and thus it is possible to thin the joint 4A. Therefore, the stiffness of the joint 4A is further reduced. As a result, the shake correction of the mounting portion 3 can be carried out with a small force.

### 3.2 Second Modified Example

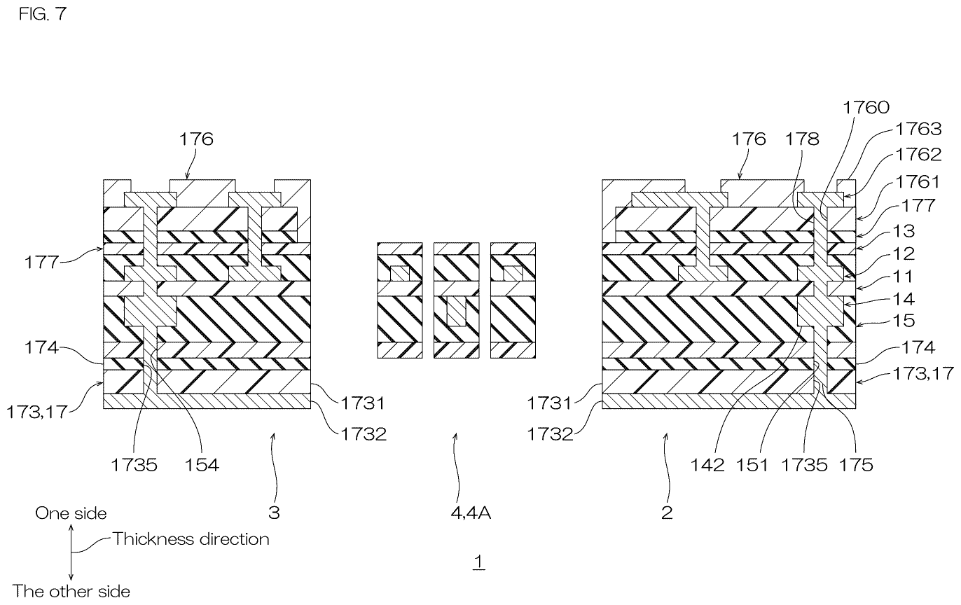

As shown in FIG. 7, in the second modified example, the support layer 17 is a rigid substrate 173. The rigid substrate 173 is adhered to the second cover insulating layer 15 through a fourth adhesive layer 174.

The rigid substrate 173 includes a third base insulating layer 1731 and a third wiring layer 1732 in order toward the other side in the thickness direction.

The third base insulating layer 1731 extends in the plane direction. The third base insulating layer 1731 is rigid. Examples of the material of the third base insulating layer 1731 include a glass-epoxy resin. The third base insulating layer 1731 has a through hole 1735. The through hole 1735 is also formed in the fourth adhesive layer 174. The third base insulating layer 1731 has a thickness of, for example, 30 μm or more, and, for example, 1000 μm or less.

The third wiring layer 1732 is electrically connected to the second wiring layer 14 through vias 175. The plurality of vias 175 are filled in the plurality of through holes 1735, respectively. The vias 175 are in contact with the third wiring layer 1732 and the second wiring layer 14. Examples of the material of the third wiring layer 1732 include copper. The third wiring layer 1732 has a thickness of, for example, 5 μm or more, and, for example, 1000 μm or less.

Each of the frame 2 and the mounting portion 3 further includes a second rigid substrate 176 in addition to the above-described rigid substrates 173. The second rigid substrate 176 is adhered to the cover insulating layer 13 through a fifth adhesive layer 177.

The second rigid substrate 176 includes a fourth base insulating layer 1761, a fourth wiring layer 1762, and a fourth cover insulating layer 1763 in order toward the one side in the thickness direction.

The fourth base insulating layer 1761 covers a part of the fourth wiring layer 1762. The fourth base insulating layer 1761 has a through hole 1760. The material of the fourth base insulating layer 1761 is the same as the material of the third base insulating layer 1731.

The material of the fourth wiring layer 1762 is the same as the material of the third wiring layer 1732. The fourth wiring layer 1762 is electrically connected to the wiring layer 12 through a via 178. The via 178 is filled in the through hole 1760.

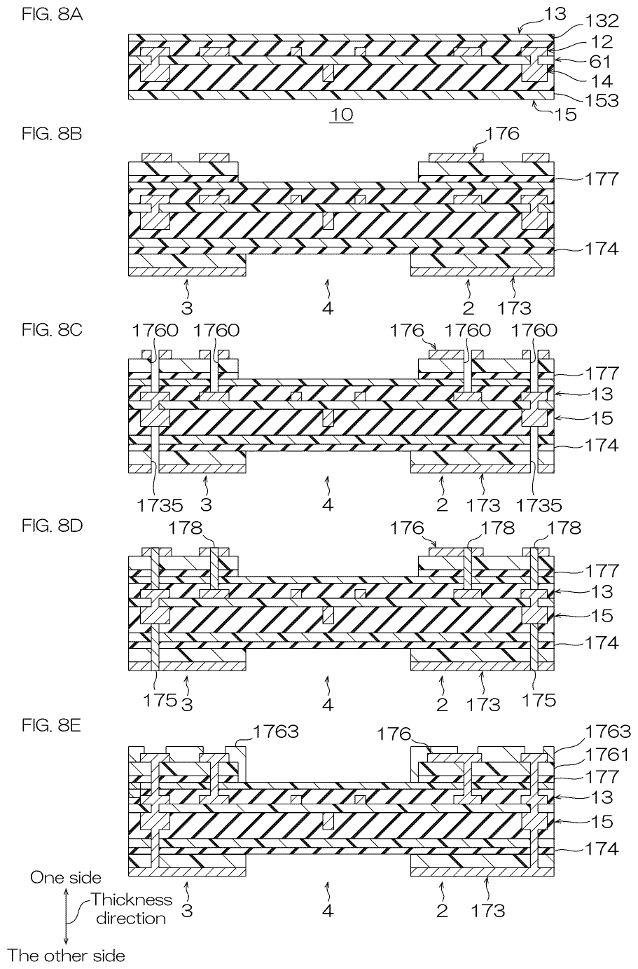

The material of the fourth cover insulating layer 1763 includes a solder resist. With reference to FIGS. 8A to 8E, a method of producing the wiring circuit board 1 of a second modified example is described.

As shown in FIG. 8A, first, the cover layer 132 and the second cover layer 153 are adhered to the base film 61 provided with the wiring layer 12 and the second wiring layer 14, thereby preparing a laminate 10.

As shown in FIG. 8B, next, the rigid substrate 173 and the second rigid substrate 176 (the fourth base insulating layer 1761 and the fourth wiring layer 1762) are adhered to a one-side surface and an other-side surface of the laminate 10, respectively. Specifically, the rigid substrates 173 is adhered to the other-side surface of the laminate 10 in the frame 2 and mounting portion 3 through the fourth adhesive layer 174. The second rigid substrate 176 is adhered to the one-side surface of the laminate 10 in the frame 2 and the mounting portion 3 through the fifth adhesive layer 177.

As shown in FIG. 8C, next, through holes 1735 and 1760 are formed. The through hole 1735 is formed in the rigid substrate 173, the fourth adhesive layer 174, and the second cover insulating layer 15. The through hole 1760 is formed in the second rigid substrate 176, the fifth adhesive layer 177, and the cover insulating layer 13. In the formation of the through holes 1735 and 1736, for example, a drilling process is used.

As shown in FIG. 8D, next, the vias 175 and 178 are formed in the through holes 1735 and 1760, respectively. In the formation of the vias 175 and 178, for example, through hole plating is used.

As shown in FIG. 8E, next, a fourth cover insulating layer 1763 is formed on a one-side surface of the fourth base insulating layer 1761 in the thickness direction. The fourth cover insulating layer 1763 is patterned by a photo process.

Thereafter, as shown in FIG. 7, the slits 421 and 422 are formed in the base insulating layer 11, the cover insulating layer 13, and the second cover insulating layer 15.

### 3.2.1 Operations and Effects of Second Modified Example

In the wiring circuit board 1, the support layer 17 is the rigid substrate 173, and thus each of the frame 2 and the mounting portion 3 has excellent stiffness. The wiring circuit board 1 can reliably support the imaging device 5 and the mounting portion 3 with the frame 2 while reliably mounting the imaging device 5 on the mounting portion 3.

Each of the frame 2 and the mounting portion 3 further includes the second rigid substrate 176, and thus it is possible to further improve the stiffness of each of the frame 2 and the mounting portion 3.

### 3.3 Third Modified Example

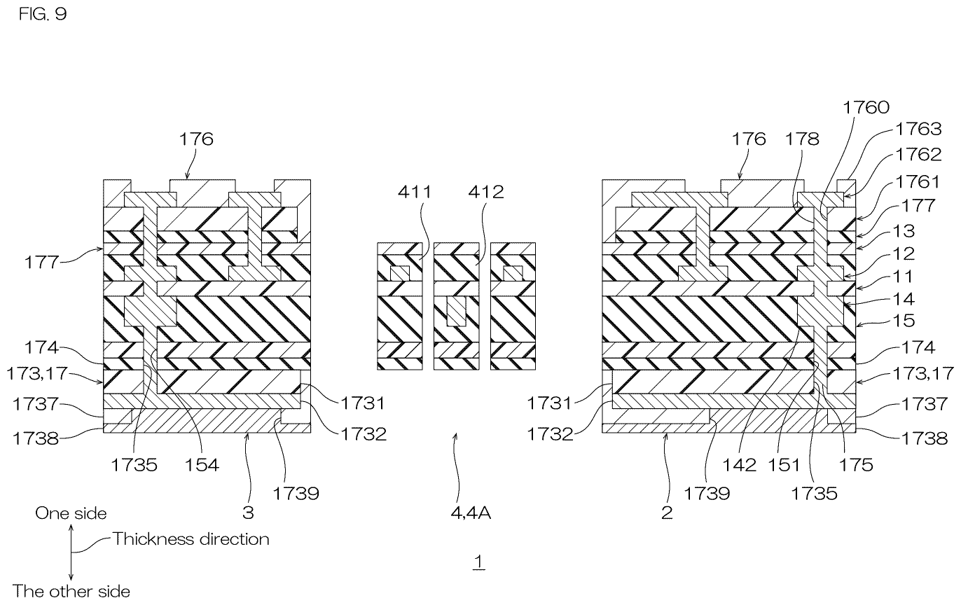

As shown in FIG. 9, in a third modified example, the rigid substrate 173 further includes an additional cover insulating layer 1737 and an additional wiring layer 1738.

The additional cover insulating layer 1737 covers a part of the third wiring layer 1732. The additional cover insulating layer 1737 has an opening 1739.

The additional wiring layer 1738 is disposed on the other-side surface of the additional cover insulating layer 1737. A part of the additional wiring layer 1738 is filled in the opening 1739.

### 3.4 Fourth Modified Example

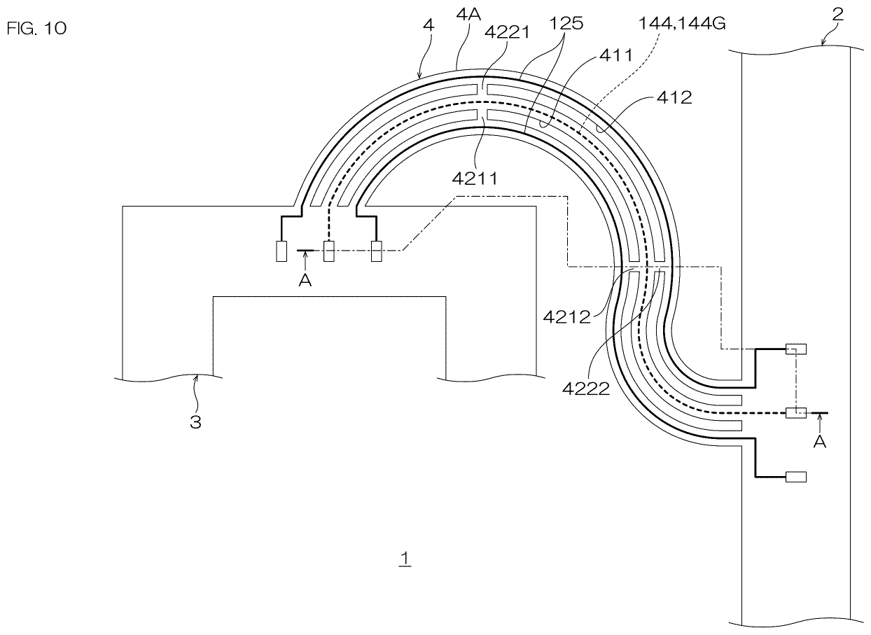

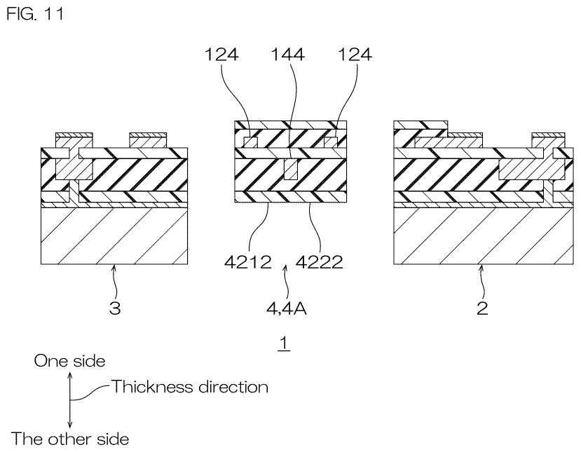

As shown in FIGS. 10 and 11, in a fourth modified example, the joint 4A includes sub-joints 4211, 4212, 4221, and 4222.

Each of the sub-joints 4211 and 4212 divides the slit 411 in a direction in which the slit 411 extends. The sub-joints 4211 and 4212 are spaced from each other in the direction in which the slit 411 extends.

The sub-joints 4221 and 4222 divide the slit 412 in a direction in which the slit 412 extends. The sub-joints 4221 and 4222 are spaced from each other in the direction in which the slit 412 extends.

As shown in FIG. 10, the sub-joints 4211 and 4221 are aligned in a direction (intersecting direction, preferably, perpendicular direction) intersecting the direction in which the joint 4 extends. The sub-joints 4212 and 4222 are aligned in the direction (intersecting direction, preferably, perpendicular direction) intersecting the direction in which the joint 4 extends.

Each of the sub-joints 4211 and 4212 connects the joint wire 125 and the second joint wire 144. As shown in FIG. 11, each of the sub-joints 4212 and 4222 connects the joint wire 125 and the second joint wire 144.

The sub-joints 4211, 4212, 4221, and 4222 include the base insulating layer 11, the cover insulating layer 13, and the second cover insulating layer 15. Specifically, the sub-joints 4211, 4212, 4221, and 4222 only include the base insulating layer 11, the cover insulating layer 13, and the second cover insulating layer 15, and do not include the wiring layer 12 and the second wiring layer 14.

According to the fourth modified example, the sub-joints 4211, 4212, 4221, and 4222 make it possible to suppress the excessive reduction in the stiffness of the joint 4 due to the slits 411 and 421. Therefore, excessive deformation of the joint 4 can be suppressed. While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICABILITY

The wiring circuit board of the present invention is preferably used, for example, for the production of imaging apparatuses.

Description of Reference Numerals

| | |
|---|---|
| 1 | Wiring circuit board |
| 2 | Frame |
| 3 | Mounting portion |
| 4, 4A, 4B, 4C, 4D | Joint |
| 11 | Base insulating layer |
| 12 | Wiring Layer |
| 121 | Frame terminal |
| 122 | Frame wire |
| 123 | Terminal |
| 124 | Wire |
| 125 | Joint wire |
| 13 | Cover insulating layer |
| 131 | Adhesive layer |
| 132 | Cover layer |
| 14 | Second wiring layer |
| 142 | Second frame wire |
| 143 | Second wire |
| 1432 | Conductive connecting portion |
| 144 | Second joint wire |
| 15 | Second cover insulating layer |
| 151 | Second cover through hole |
| 152 | Second adhesive layer |
| 153 | Second cover layer |
| 154 | Second cover through hole |
| 16 | Third adhesive layer |
| 161, 162 | Conductive adhesive layer |
| 17 | Support layer |
| 171, 172 | Metal support substrate |
| 20 | Inner peripheral edge |
| 23A, 23B, 23C, 23D | Side |
| 26 | Frame converging portion |
| 28 | Second central portion |
| 29 | Second central region |
| 30 | Outer peripheral edge |
| 33, 33A, 33B, 33C, 33D | Side |
| 34 | Central region |
| 35 | Central portion |
| 39 | Inner peripheral edge |
| 173 | Rigid substrate |
| 1731 | Third base insulating layer |
| 1732 | Third wiring layer |
| 1735, 1736 | Through hole |
| 174 | Fourth adhesive layer |
| 175 | Via |
| 176 | Second rigid substrate |
| 1761 | Fourth base insulating layer |
| 1762 | Fourth wiring layer |
| 1763 | Fourth cover insulating layer |
| 177 | Fifth adhesive layer |
| 178 | Via |
| 411, 412, 421, 422 | Slit |
| 4211, 4212, 4221, 4222 | Sub-joint |

The invention claimed is:

1. A wiring circuit board comprising:
a frame, a mounting portion surrounded by the frame and spaced from the frame, and a joint connecting the frame and the mounting portion,
wherein each of the frame and the mounting portion includes:
a base insulating layer;
a wiring layer disposed on a one-side surface of the base insulating layer in a thickness direction;
a cover insulating layer disposed on the one-side surface of the base insulating layer in the thickness direction, the cover insulating layer covering a part of the wiring layer;
a second wiring layer disposed on an other-side surface of the base insulating layer in the thickness direction; and
a second cover insulating layer disposed on the other-side surface of the base insulating layer in the thickness direction, the second cover insulating layer covering the second wiring layer,
wherein each of the frame and the mounting portion may include a support layer disposed at an other side of the second cover insulating layer in the thickness direction, and
wherein the joint does not include the support layer, and includes the base insulating layer, the wiring layer, the cover insulating layer, the second wiring layer, and the second cover insulating layer.

2. The wiring circuit board according to claim 1,
wherein the support layer is a metal support substrate.

3. The wiring circuit board according to claim 2,
wherein a thickness of the second wiring layer is different from a thickness of the wiring layer.

4. The wiring circuit board according to claim 3,
wherein each of the frame and the mounting portion further includes a third adhesive layer adhering the support layer to the second cover insulating layer.

5. The wiring circuit board according to claim 4,
wherein the third adhesive layer is a conductive adhesive layer,
wherein the second cover insulating layer in the frame and the joint has a second cover through hole,
wherein the second wiring layer includes a ground wire, and
wherein the ground wire is electrically grounded to the metal support substrate through the conductive adhesive layer having a part filled in the second cover through hole.

6. The wiring circuit board according to claim 1,
wherein the support layer is a rigid substrate including a rigid third base insulating layer and a third wiring layer in order toward the other side in the thickness direction.

7. The wiring circuit board according to claim 6,
wherein each of the frame and the mounting portion further includes a second rigid substrate including a rigid fourth base insulating layer, a fourth wiring layer, and a fourth cover insulating layer in order toward one side in the thickness direction.

8. The wiring circuit board according to claim 1,
wherein the cover insulating layer includes an adhesive layer and a cover layer in order toward one side in the thickness direction, and
wherein the second cover insulating layer includes a second adhesive layer and a second cover layer in order toward the other side in the thickness direction.

9. The wiring circuit board according to claim 1,
wherein the mounting portion has an approximately rectangular shape, and includes a side on an outer peripheral edge of the mounting portion,
wherein the frame has an approximately rectangular frame shape, and includes a facing side facing the side and a non-facing side adjacent to the facing side and not facing the side, and
wherein the joint connects the side and the non-facing side.

10. The wiring circuit board according to claim 1,
wherein the joint has a curved shape.

11. The wiring circuit board according to claim 1,
wherein the mounting portion has a side on an outer peripheral edge of the mounting portion,
wherein the joint includes a connecting portion through which the joint is connected to the side, and
wherein a ratio (a length of the connecting portion/a length of the side) of the length of the connecting portion in a direction along the side with respect to the length of the side is 0.3 or less.

12. The wiring circuit board according to claim 1,
wherein the mounting portion has a side on an outer peripheral edge of the mounting portion, and
wherein the joint is connected to a central region including a central portion of the side, the central region having a length of ½ the length of the side.

13. The wiring circuit board according to claim 12,
wherein the joint is connected to the central portion of the side.

14. The wiring circuit board according to claim 1,
wherein the mounting portion has a plurality of sides on an outer peripheral edge of the mounting portion,
wherein a plurality of the joints are provided corresponding to the plurality of sides, and
wherein among the plurality of the joints, a difference in length between a longest joint and a shortest joint is 3 mm or less.

15. The wiring circuit board according to claim 1,
wherein the joint includes the wiring layer and the second wiring layer,
wherein the wiring layer in the joint includes a joint wire,
wherein the second wiring layer in the joint includes a second joint wire spaced from the joint wire when projected in the thickness direction, and
wherein the base insulating layer, the cover insulating layer, and the second cover insulating layer in the joint have a slit disposed between the joint wire and the second joint wire.

16. The wiring circuit board according to claim 15,
wherein the slit extends along the joint wire and the second joint wire, and
wherein the joint has a sub-joint dividing the slit in a direction in which the slit extends, the sub-joint connecting the joint wire and the second joint wire.
